(19) United States
(12) Patent Application Publication
(10) Pub. No.: US 2024/0347697 A1
(43) Pub. Date: Oct. 17, 2024

(54) METHOD FOR INCREASING THE ADHESIVE STRENGTH OF ACTIVE LAYERS IN LITHIUM BATTERIES

(71) Applicant: NORCSI GMBH, Halle (DE)

(72) Inventors: Udo REICHMANN, Wilsdruff (DE); Marcel NEUBERT, Kreischa (DE); Andreas KRAUSE-BADER, Dresden (DE)

(73) Assignee: NORCSI GMBH, Halle (DE)

(21) Appl. No.: 18/682,000

(22) PCT Filed: Aug. 9, 2022
(86) PCT No.: PCT/EP2022/072294

§ 371 Date: Feb. 7, 2024

(30) Foreign Application Priority Data
Aug. 9, 2021 (DE) 10 2021 120 624.3

(51) Int. Cl. H01M 4/1395; H01M 4/02; H01M 10/0525; H01M 10/0585; H01M 10/42

(52) U.S. Cl. CPC H01M 4/1395; H01M 10/0525; H01M 10/0585; H01M 10/4235; H01M 2004/027

(57) ABSTRACT

The invention relates to a method for increasing the adhesive strength of active layers in lithium batteries, in which a silicon layer is deposited on a substrate, preferably made of copper, and subsequently subjected to rapid annealing. The problem addressed by the present invention of specifying at least one method for improving the adhesive strength of active layers in lithium batteries, in particular ensuring the bond between the current collector and the active material of the anode and at the same time a constant current contact through a continuously conductive contact layer, is solved in that prior to depositing the silicon layer on the substrate, the substrate is also subjected to rapid annealing and/or that prior to depositing the silicon layer on the substrate, a functional layer is deposited which is subjected to rapid annealing, wherein a surface of the heat-treated layer is roughened in each case

The invention relates to a method for increasing the adhesive strength of active layers in lithium batteries, wherein a first silicon layer is deposited on a substrate, preferably of copper, and is subsequently subjected to accelerated annealing.

The most straightforward way of producing silicon (Si) anodes for lithium batteries is to use Si layers on a current collector. Here, the capacitance of the battery is determined by the Si thickness.

For introductory classification, the construction of batteries is briefly elucidated. Batteries are electrochemical energy stores and are differentiated as primary and secondary batteries.

Primary batteries are electrochemical power sources in which chemical energy is converted irreversibly into electrical energy. A primary battery is therefore not rechargeable. Secondary batteries, also called accumulators, on the other hand, are rechargeable electrochemical energy stores in which the chemical reaction that takes place is reversible, enabling multiple use. During charging, electrical energy is converted into chemical energy, and on discharge it is converted back from chemical to electrical energy.

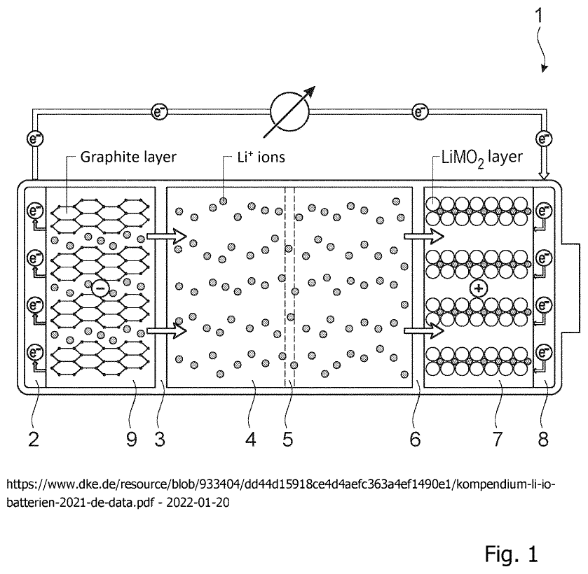

“Battery” is the headline term for interconnected cells. Cells are galvanic units which consist of two electrodes, electrolyte, separator, and cell casing. FIG. 1 shows an illustrative construction and the function of a lithium-ion cell during discharging. The constituents of a cell are briefly elucidated below.

Each Li-ion cell consists of two different electrodes: an electrode, which is negatively charged in the charged state, and an electrode, which is positively charged in the charged state. Since release of energy, in other words discharge, is accompanied by migration of ions from the negatively charged electrode to the positively charged electrode, the positively charged electrode is called the cathode and the negatively charged electrode is called the anode. The electrodes are each composed of a current collector and of an active material applied thereon. Located between the electrodes are firstly the ion-conducting electrolyte, which enables the required exchange of charge, and the separator, which ensures electrical separation of the electrodes.

The cathode consists, for example, of mixed oxides applied on an aluminum collector.

The anode of the Li-ion cell may consist of a copper foil as collector and of a layer of carbon as active material. The carbon compound used is usually natural or synthetic graphite, as it possesses a low electrode potential and exhibits little volume expansion during charging and discharging. During charging, lithium ions are reduced and intercalated into the graphite layers.

In constructions for lithium-ion batteries (LiB), the cathode typically supplies the lithium atoms for charging and discharging in the anode, and hence the battery capacity is limited by the cathode capacity. Typical cathode materials used to date are, for example, Li(Ni,Co,Mn)O₂ and LiFePO₄. Because of the construction of the cathode by lithium metal oxides, which serve for intercalation of the lithium ions on cell discharge, possibilities for boosting the capacity are minimal.

As described in the introduction, it is also known practice in Li battery anodes to supplement or replace carbon with silicon. Silicon as active material for the anode has a high storage capacity of around 3579 mAh/g for the Li₁₅Si₄ phase at room temperature, as compared with the conventional carbon-type materials, such as graphite with a storage capacity of 372 mAh/g, for example.

The capacity of the battery is determined by the thickness of the active layer, more specifically by the thickness of the Si layer. In a battery, the electrical conductivity of the active material should be made as high as possible. Silicon, as a semiconductor, has only poor conduction, in contrast to conductive graphite. Silicon therefore requires high-level doping and/or structures which increase the electrical conductivity. On a standard basis, nanoscale silicon powders are surrounded with carbon-containing framework structures and secured on the current collector.

The nature of the surface between the active material and the electrolyte is a critical determinant of the permeability for lithium ions. The surface is decisive for contact with the electrolyte and the breakdown products thereof with the active layer. On cell operation, the electrolyte decomposes and undergoes partial reaction with the electrode material. A protective layer is formed (the SEI, solid electrolyte interphase) which prevents further decomposition and reaction of the electrolyte with the active layer, without critically hindering the permeability for lithium ions. An objective of a stable battery construction, accordingly, is a thin and continuous stratum of SEL The amount of electrolyte decomposed is dependent on the size of the surface.

In WO 2017/140581 A1, a method is described for producing silicon-based anodes for secondary batteries. In this process, a metal substrate, serving as an integrated current collector, has a silicon layer deposited thereon and is then subjected to flash-lamp annealing. The purpose of the flash-lamp annealing is to promote the metal-induced layer exchange process and/or the crystallization between metal substrate and silicon layer, and to increase the adhesion. Multiple strata increase the stability and capacity of a battery. The strata are the various layers of a layered construction of the Si electrode (anode). The layered construction is also referred to as a multistratum construction or multistratum structure.

The adhesion of the strata, especially of silicon, is greatly influenced by the roughness of the surface on which the silicon is applied. High roughness generates a fine-limbed construction of the silicon stratum, so improving the adhesion. Given sufficient roughness of the surface, shadowing effects result in the additional formation of cavities and thereby separated nano- or microstructures. In battery production, the targeted construction of these small-particle structures of active material is not only able to improve the adhesion; instead, the nano- or microstructures are also beneficial to battery run time, since they allow the volume expansion in the anode material to be accommodated by the free space between the nanostructures, and the reduced size of the structures facilitates the phase transitions during formation of alloy, leading to a performance boost for the anode material.

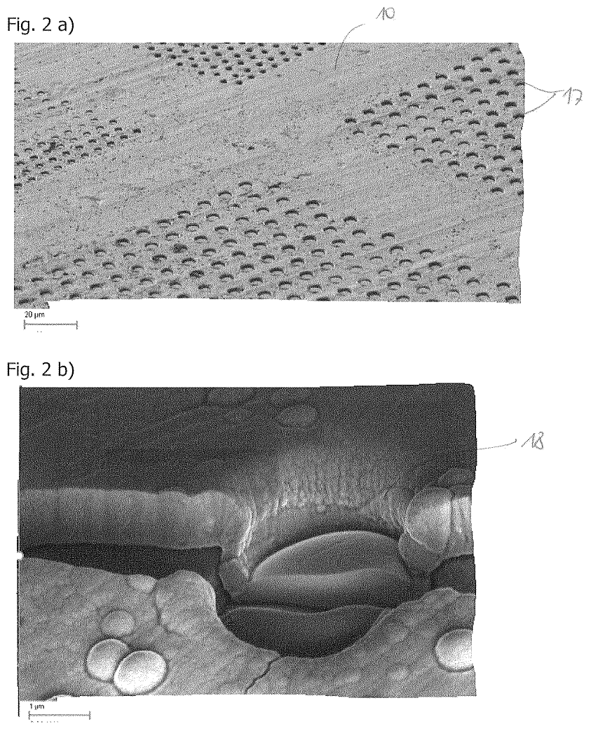

A rough surface serves in general to boost the mechanical adhesion of the strata to one another. Metallic surfaces are roughened primarily by wet- or dry-chemical etching of the surface. Dry etching methods include plasma etching or reactive ion beam etching. A further possibility is that of targeted uneven deposition of metal onto the surface, with uneven deposition referring to a form of deposition wherein the metal atoms are laid down on the surface in a non-uniform manner. This is done using typical deposition methods where the surface energy has an influence over the layer construction. Chemical deposition, such as electrochemical deposition at high current densities, for example, results in a roughened surface. Roughening may likewise be accomplished by a material whose cohesion forces are greater than the adhesion forces—for example, a gold layer on carbon, which is annealed. Mechanical roughening, such as the embossing of structures into a copper foil which are subsequently transferred to the deposited silicon (see FIG. 2), is a further variant for increasing the roughness of the surface. However, the roughening operations are costly and/or technologically demanding and have hitherto prevented market establishment in battery-making. Fraunhofer IWS (Piwko, M. et al. Journal of Power Sources 351, 183-191 (2017)) makes use, for example, of a copper foil which is roughened via pulsed laser ablation and has silicon applied to it. This produces structured columnar silicon layers which on lithium intercalation are able to freely expand and so permit a long lifetime for the LiB. Other variants are the roughening of the substrate surface with nanostructures comprising, for example, tantalum (Ta) nanoparticles before the deposition of the silicon (see Haro, M. et al. Nano-vault architecture mitigates stress in silicon-based anodes for lithium-ion batteries. Commun Mater 2, 1-10 (2021)). The high cavity content of the nanostructures and their sealed surface allow the vaulted structure to be used as a nanostructure unit which is capable of dissipating lithiation stresses (or other stresses).

The adhesion of layers can be improved, further to the mechanical adhesion, by chemical adhesion. Here, a reaction of the layer with the substrate, or an additional adhesion promoter, produces a stable connection.

For silicon or silicon-containing compounds or mixtures, or other active layers, the adhesion to the current collector is critical to a long operating life of the battery. It ensures consistent current contact in spite of the volume expansion of the silicon of up to 400% on lithium intercalation. The massive stress at the boundary layer resulting from not only lithium intercalation but also simply the inherent stress of the rigid silicon during application normally leads to a rapid loss of current contact between active material (Si) and collector (Cu) and hence to a reduction in the capacity of the battery.

It is therefore the object of the present invention to specify methods which improve the adhesive strength of active layers in lithium batteries, especially the adhesion between the current collector and the active material of the anode. At the same time, consistent current contact is to be ensured through a persistently conductive contact layer.

The object is achieved by a method of the invention according to a first variant of independent claim 1. In the method for increasing the adhesive strength of active layers in lithium batteries, wherein a silicon layer is deposited on a substrate, preferably of copper, and is subsequently subjected to accelerated annealing, the substrate, before the deposition of the silicon layer on the substrate, is likewise subjected to accelerated annealing, thereby roughening the surface of the substrate.

The accelerated annealing causes partial melting of the surface of the substrate. Depending on the properties of the substrate surface and on the accelerated annealing energy employed, the substrate surface can be roughened in a targeted way. Accelerated annealing refers in particular to flash-lamp annealing and/or laser annealing. Flash-lamp annealing takes place with a pulse duration or annealing time in the range from 0.3 to 20 ms and with a pulse energy in the range from 0.3 to 100 J/cm². In the case of laser annealing, the annealing time of 0.01 to 100 ms is established by the rate of scanning of the local heating site, to generate an energy density of 0.1 to 100 J/cm². The heating ramps achieved in the accelerated annealing are situated in the range, necessary for the method, of 10\hat{ }4-10\hat{ }7 K/s. Flash-lamp annealing for this purpose utilizes a spectrum in the visible wavelength range, whereas for laser annealing, discrete wavelengths in the range of the infrared (IR) to ultraviolet (UV) spectrum are used. A high energy or high absorption of the energy of the flashlamp or laser provides for the partial melting of the surface. On solidification, the surface atoms are rearranged into a rough structure. The faster the cooling of the substrate surface, the more fine-grained or fine-limbed the substrate surface becomes, this surface therefore being rougher than without this process step.

The roughening of the substrate surface solely by accelerated annealing represents a very simple process, requiring no additional material. It is therefore readily possible to perform this process step of accelerated annealing under vacuum, meaning that, for a downstream deposition process to be performed in a vacuum facility, no interruption of the vacuum is required and hence oxidation of the material surface is prevented. In some cases, however, a high accelerated annealing energy is required for the partial melting.

The object is likewise achieved by an alternative according to independent claim 1. In the method for increasing the adhesive strength of active layers in lithium batteries, wherein a silicon layer is deposited on a substrate, preferably of copper, and is subsequently subjected to accelerated annealing, a functional layer is deposited on the substrate before the deposition of the silicon layer and is subsequently subjected to accelerated annealing, thereby roughening the surface of the functional layer. The functional layer reacts with the substrate, producing a high level of adhesion, and at the same time the surface of the functional layer is roughened. This is followed by deposition of the silicon layer on the new surface, this layer being then likewise subjected to accelerated annealing, for the controlled diffusion and formation of copper silicide.

By a functional layer is meant a layer which fulfills, exhibits or influences a predetermined property or effect. This may be, for example, the adhesive strength, conductivity or absorption. The purpose of applying an additional functional layer to the substrate is to bring about preliminary functionalization of the surface. This layer may be applied, for example, by sputtering or vaporization. The layer acts as an absorber, and so the absorption of the flash or laser is significantly increased and the flash energy or laser energy can be reduced. Carbon, for example, is easy to apply as an absorption layer and is correspondingly cost-effective.

The process of depositing a functional layer on to the substrate, and of the subsequent accelerated annealing, may be repeated multiply; the aim is to generate a reaction layer which is rougher than the original surface and which moderates the diffusion of the copper into subsequent layers.

In one advantageous embodiment of the method alternative of the invention, more than one functional layer is deposited on the substrate, forming a layer stack which is subsequently subjected to accelerated annealing. A layer stack or multiple stack is easy to realize in the process procedure. Subsequently, accelerated annealing takes place for the purpose of roughening the surface. After that, the active material of the lithium battery is deposited, and adheres more effectively to the existing construction. The accelerated annealing of the active layer of silicon enables not only the physical adhesion but also a reaction with the pretreated substrate, such as a reaction of Si to form a silicide, for example. Silicides crystallize in an unordered structure, forming a rough surface. This surface may serve as a surface with good adhesion for the further electrode construction.

A layer stack consists of a plurality of functional layers, the application thereof making sense when multiple properties have a positive effect on a roughening of the surface which cannot, however, be fulfilled by one material. Carbon possesses good absorption properties, allowing the temperature of the surface to be increased by accelerated annealing, but it does not react with copper. This differentiates it from a metal such as nickel, which possesses good reflexion properties but reacts well with copper. The two materials, i.e., carbon and nickel, are able together in a layer stack to generate high surface roughness.

A further advantage of a layer stack is the homogenization of the distribution of materials and also the dissipation of stress in the strata of the layer stack and in the substrate. A stratum denotes a layer of the layer stack that is constructed of at least two layers.

In a different embodiment of the method of the invention, the functional layer deposited comprises a silicon layer and/or a further functional layer, which is subjected to accelerated annealing to roughen the deposited functional layer. This has the advantage that further layers for deposition likewise have good adhesion to the existing layer construction, as a result of the roughened surface, and the functional layers may serve, for example, as diffusion barriers, for developing a graduated course of the metal silicide concentration, more particularly of the copper silicide concentration, in the layer stack, which can be used as an active layer of an anode in a lithium battery.

It is desirable to perform as few accelerated annealing operations as possible, in order to keep the energy costs low. It is advantageous if a first deposited layer is treated with a high energy input in order to bring about complete and concluded reaction of the layer atoms for generating a rough stratum/layer of the layer stack. Subsequently, accelerated annealing operations with lower energy than for the first layer stratum deposition can take place, in order to stabilize a layer stack constructed of multiple functional layers/strata, but to prevent the reaction as in the first stratum/layer.

In one embodiment of the method of the invention, the functional layer and/or the layer stack is formed and deposited from at least one of the materials titanium (Ti), nickel (Ni), aluminum (Al), tin (Sn), gold (Au), silver (Ag), copper (Cu), silicon (Si), molybdenum (Mo), carbon (C) and/or tungsten (W). The materials for the functional layer or functional layer strata of the layer stack are selected according to the desired properties of the final lithium battery construction.

In a further embodiment of the method of the invention, the functional layer deposited comprises an absorption layer.

The purpose of applying a functional layer to the substrate is to bring about preliminary functionalization of the surface. This layer may be applied, for example, by sputtering or vaporization. Through an absorption layer, the absorption of the flash or laser is significantly increased and the flash energy or laser energy can be reduced. Carbon, for example, is easy to apply as an absorption layer and is correspondingly cost-effective.

In a further advantageous embodiment of the method of the invention, the flash-lamp annealing is carried out with a pulse duration in the range from 0.3 to 20 ms, with a pulse energy in the range from 0.3 to 100 J/cm² and with preheating or cooling in the range from 4° C. to 200° C., so that a roughness of the respectively deposited layer is adjusted to a roughness value of Ra=200 nm up to Ra=3 μm.

In a different further embodiment of the method of the invention, the laser annealing is carried out with a pulse duration in the range from 0.01 to 100 ms, with a pulse energy in the range from 0.3 to 100 J/cm² and with preheating or cooling in the range from 4° C. to 200° C., so that a roughness of the respectively deposited layer is adjusted to a roughness value of Ra=200 nm up to Ra=3 μm.

Advantageous in one application is the use of a metal substrate, composed of copper, for example, for producing a silicon-based anode, in which case a silicon layer is deposited on the metal substrate and is subsequently subjected to accelerated annealing, the metal substrate having a roughness of Ra=0.2 μm to Ra=3.0 μm. In the methods of the invention, effective adhesion is obtained utilizing both the adhesion due to the pure physical roughness, and the chemisorption too.

The object is achieved by a further alternative method of the invention according to independent claim 10. In the method for increasing the adhesive strength of active layers in lithium batteries, wherein a silicon layer is deposited on a substrate, preferably of copper, and is subsequently subjected to accelerated annealing, after the deposition of the silicon layer on the substrate, a heterogeneous layer stack is deposited which is selectively etched. The selective etching of the surface brings about roughening of the surface. The roughness can be adjusted by the etching parameters that are used. For the aforementioned purpose, etching parameters as follows are advantageous: CuCl₃, Cu₂SO₄, H₂SO₄, HF in total concentrations below 5% for slow copper/silicon/silicide etching. The roughness is situated in the range from Ra=0.4 μm to Ra=3 μm. The aim is always to obtain a roughness which is not only better/higher than that of the pure substrate but also better/higher than that of the layer deposited and reacted through the accelerated annealing; the copper substrate, with a thickness below 20 μm, must not be destroyed.

A heterogeneous layer stack is a layer of reacted and unreacted parts; for example, pure silicon may be surrounded by a conductive copper silicide matrix.

The advantages of the methods and method variants of the invention are that the roughening can be integrated into an existing deposition process for anode production, and the accelerated annealing is possible in-line without special pretreatments. The use of materials which are also utilized in anode construction enables a simple surface structuring with the flash-lamp annealing. The subsequent reaction between the applied silicon layer with the copper substrate produces very good adhesion and, in addition, a very good electrical transition, with no need for any extra material other than the silicon. The copper comes from a Cu foil substrate.

It is true that the application of the functional layer as an additional process step does extend the process of production of silicon anodes for lithium batteries and makes no contribution to increasing the capacity of the anode, since copper silicide has little or no capacity for intercalation of lithium, or the intercalation is an irreversible process; however, this is outweighed by the advantage of the good adhesion between the current collector and the active material of the anode, with the good adhesion ensuring a homogeneous and stable electrical transition for battery operation.

The adhesive strength of functional layers in lithium batteries wherein a silicon layer is deposited on a substrate, preferably of copper, and is subsequently subjected to accelerated annealing may likewise be increased if the silicon layer is formed from silicon particles, silicon nanoparticles and/or silicon nanowires, with the subsequent deposition of a functional layer thereon and subsequent subjection to accelerated annealing.

The application of silicon prior to introduction into a coating facility can significantly lower the costs of the process. Silicon can be acquired commercially in the form of particles, nanoparticles or nanowire. As a result of application to copper and of subsequent accelerated annealing, the silicon reacts with the copper and forms a very rough surface, which can subsequently be used further for anode construction. The adhesion and the electrical conductivity are very good as a result of the reaction of Si and Cu. With this option it is possible to avoid diverse pretreatments, examples being the etching of the copper surface, the nanowire growth, and the reaction of Si with Cu via oven processes. A process of this kind is able to take place without vacuum.

Because of the pre-preparation of the Cu substrate surface with silicon, the deposition processes in the process facility can be simplified, with the production process now only requiring subsequent depositions onto a substrate already activated with silicon. The pre-preparation of the substrate may take place with any desired particle sizes between 1 nm and 5 μm in diameter. It must be ensured, however, that the particles have a homogeneous distribution and adhesion on the copper substrate.

The invention is elucidated in more detail below with reference to exemplary embodiments.

In the drawings

FIG. 1 shows an illustrative construction and function of a lithium-ion cell during discharging;

FIG. 2 shows SEM micrographs of a mechanically roughened Si surface (b) as a variant of an ordered structure by means of embossed structures into a copper substrate (a), which are transferred to the deposited silicon to increase the adhesive strength;

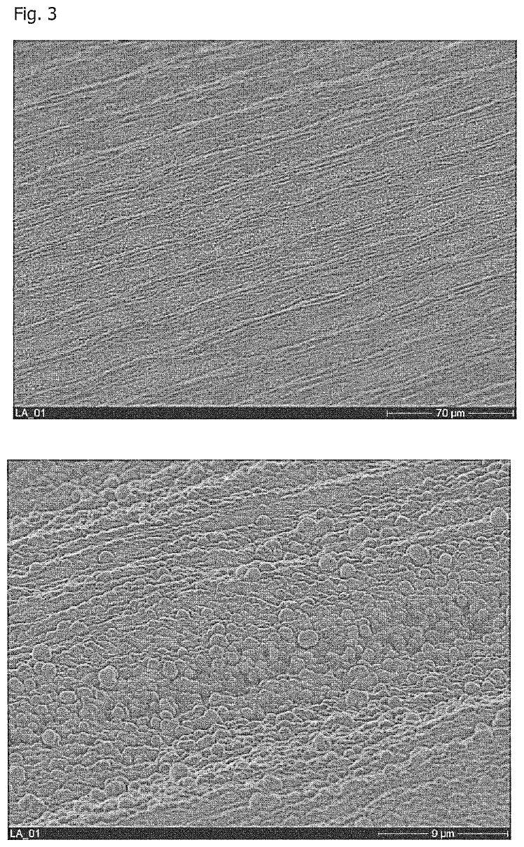

FIG. 3 shows an SEM micrograph of a surface roughened via laser ablation to increase the adhesive strength;

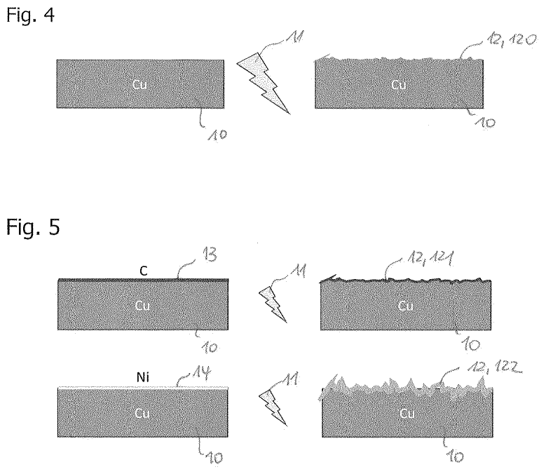

FIG. 4 shows a schematic representation of the method of the invention according to a first variant as per claim 1;

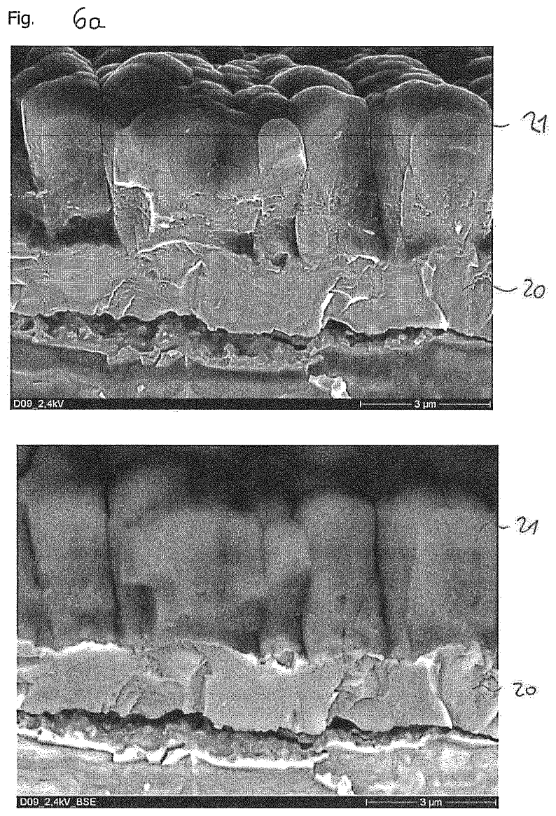

FIG. 5 shows a schematic representation of the method of the invention according to a second variant as per claim 1;

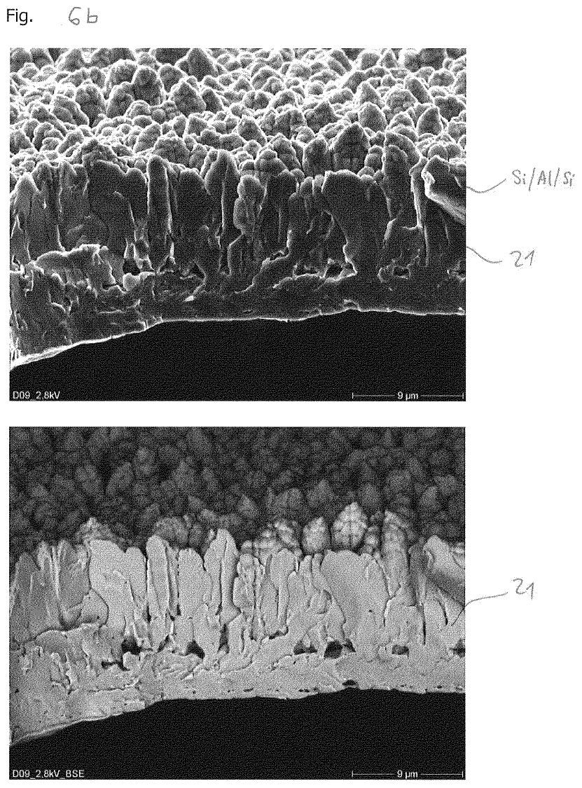

FIG. 6 shows SEM micrographs a) and b) of a surface, roughened via the method of the invention, of a functional layer of silicon with subsequent accelerated annealing, more particularly flash-lamp annealing, leading to a columnar growth of silicon mixed with aluminum.

FIG. 4 shows the method of the invention according to a first variant as per claim 1. The substrate 10, a copper foil for example, serving as current collector, is subjected to accelerated annealing, more particularly flash-lamp annealing 11. The flash-lamp annealing 11 causes the copper foil 10 to melt. As soon as the energy input by the flash-lamp pulse, which lasts only 0.1 to 10 ms, comes to an end, the substrate material 10 resolidifies and leads to roughening 12, 120 of the substrate surface. This method variant requires a high energy input.

FIG. 5 shows the method of the invention according to a second variant as per claim 1. On the substrate 10, which can be a copper foil and acts as current collector, a first functional layer 13, of carbon, for example, is applied and is subjected to accelerated annealing, more particularly flash-lamp annealing 11. The carbon layer 13 significantly increases the absorption and at the same time leads to roughening 12, 121 of the surface. The use of carbon has the advantage that carbon in the form of graphite is already utilized in lithium-ion battery production and can therefore be incorporated easily and compatibly into the production process. Another advantage is that the sputtered carbon layer 121 can be used as a brake on copper diffusion and hence lessens the formation of silicide, since copper atoms from the substrate are hindered from entering the subsequently applied silicon and reacting with the silicon layer. Carbon additionally has the advantage that it is very lightweight and also electrically conductive, and lithium can diffuse through it readily. The weight, and the good electrical and ionic conductivity, are advantages relative to all other metals for use in the intermediate layer. A disadvantage, however, is that the subsequent silicon layer does not adhere sufficiently on a carbon layer. For assistance, an additional metal layer 14, nickel for example, is applied to the carbon layer. This metal layer 14 leads to additional roughening 12, 122 and assists the adhesion by a reaction between nickel and silicon. Good adhesion is ensured as a result.

The deposition of silicon is not represented in FIGS. 4 and 5.

FIGS. 6a and 6b each show a micrograph of a functional layer surface roughened by means of the method of the invention: in the present example, the surface of an aluminum stratum introduced in a silicon layer, after accelerated annealing, more particularly flash-lamp annealing, which promotes columnar growth of silicon/silicides 21. The stratum structure in the example depicted consists of Si/Al/Si, which has been flash-treated with a high flash energy. A stratum structure is no longer apparent; instead, the recognizable columnar structures are formed. These structures come about by the aluminum with the silicon forming a solid solution/amorphous solid which develops these structures below the melting temperature of silicon. As a result of the roughening, there is island growth of the deposited silicon 21. Columnlike silicon structures are formed and, through the reaction with metal atoms, silicide structures as well (FIG. 6b). The two SEM micrographs in FIG. 6a and in FIG. 6b each show the same structural detail of the sample, with these micrographs differing in terms of the selected detector.

### LIST OF REFERENCE SIGNS

1 lithium-ion battery
2 collector on anode side
3 SEI—solid-electrolyte interphase
4 electrolyte
5 separator
6 conducting interphase
7 cathode, positive electrode
8 collector on cathode side
9 anode, negative electrode
10 substrate, e.g., copper foil
11 accelerated annealing, more particularly flash-lamp annealing and/or laser annealing
12 roughened surface after accelerated annealing
120 roughened surface of copper
121 roughened surface of carbon
122 roughened surface of nickel
13 carbon layer
14 nickel layer
17 embossed structures in a copper substrate
18 structured silicon layer generated by embossing
19 columnar Si structures
20 aluminum stratum
21 silicon/silicide

1. A method for increasing the adhesive strength of active layers in lithium batteries, wherein a silicon layer is deposited on a substrate, preferably of copper, and is subsequently subjected to accelerated annealing, characterized in that before the deposition of the silicon layer on the substrate, the substrate is likewise subjected to accelerated annealing and/or in that before the deposition of the silicon layer on the substrate, a functional layer is deposited which is subjected to accelerated annealing, thereby in each case roughening a surface of the flash-treated layer.

2. The method as claimed in claim 1, characterized in that more than one functional layer is deposited on the substrate, forming a layer stack which is subsequently subjected to accelerated annealing.

3. The method as claimed in claim 1, characterized in that the functional layer deposited comprises a silicon layer and/or a further functional layer which is subjected to accelerated annealing, thereby roughening the deposited layer.

4. The method as claimed in claim 1 3, characterized in that the functional layer and/or the layer stack are/is formed from at least one of the materials titanium (Ti), nickel (Ni), aluminum (Al), tin (Sn), gold (Au), silver (Ag), copper (Cu), silicon (Si), molybdenum (Mo), carbon (C) and/or tungsten (W).

5. The method as claimed in claim 1, characterized in that the functional layer deposited comprises an absorption layer.

6. The method as claimed in claim 5, characterized in that the absorption layer deposited comprises carbon.

7. The method as claimed in claim 1, characterized in that the flash-lamp annealing is carried out with a pulse duration in the range from 0.3 to 20 ms, with a pulse energy in the range from 0.3 to 100 J/cm² and with preheating or cooling in the range from 4° C. to 200° C., so that a roughness of the respectively deposited layer is adjusted to a roughness value of Ra=200 nm up to Ra=3 μm.

8. The method as claimed in claim 1, characterized in that the laser annealing is carried out with a pulse duration in the range from 0.01 to 100 ms, with a pulse energy in the range from 0.3 to 100 J/cm² and with preheating or cooling in the range from 4° C. to 200° C., so that a roughness of the respectively deposited layer is adjusted to a roughness value of Ra=200 nm up to Ra=3 μm.

9. The use of a metal substrate for producing a silicon-based anode, wherein a silicon layer is deposited on the metal substrate and is subsequently subjected to accelerated annealing, the metal substrate having a roughness of 0.2 μm to 3 μm.

10. A method for increasing the adhesive strength of active layers in lithium batteries, wherein a silicon layer is deposited on a substrate, preferably of copper, and is subsequently subjected to accelerated annealing, characterized in that after the deposition of the silicon layer on the substrate, a heterogeneous layer stack is deposited which is selectively etched, thereby roughening the silicon layer.

11. The method as claimed in claim 10, characterized in that the etching parameters of CuCl₃, Cu₂SO₄, H₂SO₄, HF in a total concentration below 5% for copper/silicon/silicide are used to establish a roughness of Ra=0.4 μm to Ra=3 μm.
